(19) United States
(12) Patent Application Publication
(10) Pub. No.: US 2019/0207098 A1
(43) Pub. Date: Jul. 4, 2019

(54) VERTICAL COMPOUND SEMICONDUCTOR FOR USE WITH A PERPENDICULAR MAGNETIC TUNNEL JUNCTION (PMTJ)

(71) Applicant: Spin Memory, Inc., Fremont, CA (US)

(72) Inventors: Kuk-Hwan Kim, San Jose, CA (US); Dafna Beery, Palo Alto, CA (US); Amitay Levi, Cupertino, CA (US); Andrew J. Walker, Mountain View, CA (US)

(21) Appl. No.: 15/859,116

(22) Filed: Dec. 29, 2017

(51) Int. Cl. H01L 43/10; G11C 11/16; H01L 43/02; H01L 43/12

(52) U.S. Cl. CPC H01L 43/10; H01L 43/12; H01L 43/02; G11C 11/161

(57) ABSTRACT

According to one embodiment, an apparatus includes a channel layer positioned above a substrate in a film thickness direction, the channel layer including a lower channel layer positioned below an upper channel layer in the film thickness direction, a gate dielectric layer positioned on sides of the channel layer, a gate layer positioned on sides of the gate dielectric layer, and an electrode layer positioned above an upper portion of the channel layer in the film thickness direction. Sides of the electrode layer extend beyond sides of the channel layer in an element thickness direction perpendicular to the film thickness direction. Other systems and methods of manufacturing thereof are described in accordance with more embodiments.

### FIELD OF THE INVENTION

The present invention relates to magnetic random access memory (MRAM), and more particularly to providing a vertical compound semiconductor for use with a perpendicular magnetic tunnel junction (pMTJ).

### BACKGROUND

Magnetic Random Access Memory (MRAM) is a non-volatile data memory technology that stores data using magnetoresistive cells, such as Magnetoresistive Tunnel Junction (MTJ) elements. At their most basic level, such MTJ elements include first and second magnetic layers that are separated by a thin, non-magnetic tunnel barrier layer, which may be constructed of an insulating barrier material, such as MgO, Al₂O₃, etc. The first magnetic layer, which may be referred to as a reference layer, has a magnetization that is fixed in a direction that is perpendicular to that of a plane of the layer. The second magnetic layer has a magnetization that is free to move so that it may be oriented in either of two directions that are both generally perpendicular to the plane of the free magnetic layer. Therefore, the magnetization of the free layer may be either parallel with the magnetization of the reference layer or anti-parallel with the direction of the reference layer (i.e., opposite to the direction of the reference layer).

The electrical resistance through the MTJ element in a direction perpendicular to the planes of the layers changes with the relative orientations of the magnetizations of the magnetic reference layer and magnetic free layer. When the magnetization of the magnetic free layer is oriented in the same direction as the magnetization of the magnetic reference layer, the electrical resistance through the MTJ element is at its lowest electrical resistance state. Conversely, when the magnetization of the magnetic free layer is in a direction that is opposite to that of the magnetic reference layer, the electrical resistance across the MTJ element is at its highest electrical resistance state.

The switching of the MTJ element between high and low resistance states results from electron spin transfer. Each electron has a spin orientation. Generally, electrons flowing through a conductive material have random spin orientations with no net spin orientation. However, when electrons flow through a magnetized layer, the spin orientations of the electrons become aligned so that there is a net aligned orientation of electrons flowing through the magnetic layer, and the orientation of this alignment is dependent on the orientation of the magnetization of the magnetic layer through which they travel. When the orientations of the magnetizations of the free layer and the reference layer are oriented in the same direction, the spin of the electrons in the free layer are generally in the same direction as the orientation of the spin of the electrons in the reference layer. Because these electron spins are generally in the same direction, the electrons may pass relatively easily through the tunnel barrier layer. However, if the orientations of the magnetizations of the free layer and the reference layer are opposite to one another, the spin of electrons in the free layer will generally be opposite to the spin of electrons in the reference layer. In this case, electrons do not easily pass through the barrier layer, resulting in a higher electrical resistance through the MTJ stack.

Because the MTJ element may be switched between low and high electrical resistance states, it may be used as a memory element to store data. For example, the low resistance state may be read as a “1” or one, whereas the high resistance state may be read as a “0” or zero. In addition, because the magnetic orientation of the magnetic free layer remains in its switched state without any electrical power being provided to the element, the memory storage provided by the MTJ element is robust and non-volatile.

To write a bit of data to the MTJ cell, the magnetic orientation of the magnetic free layer is switched from a first direction to a second direction that is 180° from the first direction. This may be accomplished, for example, by applying a current through the MTJ element in a direction that is perpendicular to the planes of the layers of the MTJ element. An electrical current applied in one direction will switch the magnetization of the free layer to a first orientation, whereas an electrical current applied in a second direction will switch the magnetic of the free layer to a second, opposite orientation.

Once the magnetization of the free layer has been switched by the current, the state of the MTJ element may be read by detecting a voltage across the MTJ element, thereby determining whether the MTJ element is in a “1” or “0” bit state. Advantageously, once the switching electrical current has been removed, the magnetic state of the free layer will remain in the switched orientation until some other time when an electrical current is applied to switch the MTJ element to the opposite state. Therefore, the recorded data bit is non-volatile in that it remains intact (the magnetic orientation of the free layer does not change) in the absence of any electrical current being supplied.

### SUMMARY

According to one embodiment, a method includes forming a mask layer above a substrate in a film thickness direction, removing a portion of the mask layer to expose a portion of the substrate therethrough, the portion of the substrate having a predetermined size, doping the portion of the substrate, forming a channel layer above the doped portion of the substrate, with the channel layer extending beyond the mask layer in the film thickness direction, forming an insulative layer above the channel layer and the mask layer in the film thickness direction, and on sides of the channel layer, forming a gate layer above the insulative layer in the film thickness direction, forming a second insulative layer above the gate layer in the film thickness direction, removing portions of the insulative layer, the gate layer, and the second insulative layer to expose an upper portion of the channel layer, and forming an electrode layer above the upper portion of the channel layer in the film thickness direction to form a nanowire. Sides of the electrode layer extend beyond sides of the channel layer in an element thickness direction perpendicular to the film thickness direction.

In another embodiment, a method includes forming an etch-stop layer above a substrate in a film thickness direction, forming a sacrificial layer above the etch-stop layer in the film thickness direction, removing portions of the sacrificial layer and the etch-stop layer to form a pillar having a predetermined size, forming an insulative layer above the pillar and exposed portions of the substrate that are not covered by the pillar in the film thickness direction, removing portions of the insulative layer to thin the insulative layer and expose an upper surface of the pillar, removing all remaining portions of the sacrificial layer to form a channel mold, forming a channel layer above the etch-stop layer within the channel mold, where the channel layer extends to a height of the channel mold in the film thickness direction, removing the channel mold, forming a gate dielectric layer above the substrate and the channel layer in the film thickness direction, and along sides of the etch-stop layer and the channel layer, forming a second insulative layer above portions of the gate dielectric layer that are positioned directly above the substrate, the second insulative layer having a height in the film thickness direction less than half of a height of the channel layer in the film thickness direction, forming a gate layer above the second insulative layer, the gate layer having a height in the film thickness direction that is less than the height of the channel layer in the film thickness direction, and forming an electrode layer directly above the channel layer to form a nanowire. Sides of the electrode layer extend beyond sides of the channel layer in an element thickness direction perpendicular to the film thickness direction.

In accordance with another embodiment, an apparatus includes a channel layer positioned above a substrate in a film thickness direction, the channel layer including a lower channel layer positioned below an upper channel layer in the film thickness direction, a gate dielectric layer positioned on sides of the channel layer, a gate layer positioned on sides of the gate dielectric layer, and an electrode layer positioned above an upper portion of the channel layer in the film thickness direction. Sides of the electrode layer extend beyond sides of the channel layer in an element thickness direction perpendicular to the film thickness direction.

These and other features and advantages of the invention will be apparent to one of skill in the art upon reading of the following detailed description of the embodiments in conjunction with the figures. In the figures, like reference numerals used in more than one figure indicate a like element, and may be considered in light of the description of the like element presented in any of the other figures having the like element.

### BRIEF DESCRIPTION OF THE DRAWINGS

For a fuller understanding of the nature and advantages of this invention, as well as the preferred mode of use, reference should be made to the following detailed description read in conjunction with the accompanying drawings. The drawings are not presented to scale unless specified otherwise on an individual basis.

FIG. 1 is a schematic, cross-sectional view of a portion of a magnetic memory element, which may be used in embodiments of the invention.

FIG. 2 is a schematic, cross-sectional view of a portion of a magnetic random access memory (MRAM) that includes a magnetoresistive sensor, which may be used in embodiments of the invention.

FIGS. 3A-3K show various structures created during manufacture of a vertical compound semiconductor according to one embodiment.

FIGS. 4A-4P show various structures created during manufacture of a vertical compound semiconductor, in another embodiment.

FIG. 5 shows a vertical compound semiconductor according to one embodiment.

FIG. 6 shows a circuit diagram of a portion of an acceptor structure according to one embodiment.

### DETAILED DESCRIPTION

The following description includes the best embodiments presently contemplated for carrying out the invention. This description is made for the purpose of illustrating the general principles of this invention and is not meant to limit the inventive concepts claimed herein in any way.

Unless otherwise specifically defined herein, all terms are to be given their broadest possible interpretation including meanings implied from the specification as well as meanings understood by those skilled in the art and/or as defined in dictionaries, treatises, etc. It must also be noted that, as used in the specification and the appended claims, the singular forms “a,” “an,” and “the” include plural referents unless otherwise specified.

Moreover, the term “about” when used herein to modify a value indicates a range that includes the value and less and greater than the value within a reasonable range. In the absence of any other indication, this reasonable range is plus and minus 10% of the value. For example, “about 10 nanometers” indicates 10 nm ±1 nm, such that the range includes all values in a range including 9 nm up to and including 11 nm.

Also, the term “comprise” indicates an inclusive list of those elements specifically described without exclusion of any other elements. For example, “a list comprises red and green” indicates that the list includes, but is not limited to, red and green. Therefore, the list may also include other colors not specifically described.

According to one general embodiment, a method includes forming a mask layer above a substrate in a film thickness direction, removing a portion of the mask layer to expose a portion of the substrate therethrough, the portion of the substrate having a predetermined size, doping the portion of the substrate, forming a channel layer above the doped portion of the substrate, with the channel layer extending beyond the mask layer in the film thickness direction, forming an insulative layer above the channel layer and the mask layer in the film thickness direction, and on sides of the channel layer, forming a gate layer above the insulative layer in the film thickness direction, forming a second insulative layer above the gate layer in the film thickness direction, removing portions of the insulative layer, the gate layer, and the second insulative layer to expose an upper portion of the channel layer, and forming an electrode layer above the upper portion of the channel layer in the film thickness direction to form a nanowire. Sides of the electrode layer extend beyond sides of the channel layer in an element thickness direction perpendicular to the film thickness direction.

In another general embodiment, a method includes forming an etch-stop layer above a substrate in a film thickness direction, forming a sacrificial layer above the etch-stop layer in the film thickness direction, removing portions of the sacrificial layer and the etch-stop layer to form a pillar having a predetermined size, forming an insulative layer above the pillar and exposed portions of the substrate that are not covered by the pillar in the film thickness direction, removing portions of the insulative layer to thin the insulative layer and expose an upper surface of the pillar, removing all remaining portions of the sacrificial layer to form a channel mold, forming a channel layer above the etch-stop layer within the channel mold, where the channel layer extends to a height of the channel mold in the film thickness direction, removing the channel mold, forming a gate dielectric layer above the substrate and the channel layer in the film thickness direction, and along sides of the etch-stop layer and the channel layer, forming a second insulative layer above portions of the gate dielectric layer that are positioned directly above the substrate, the second insulative layer having a height in the film thickness direction less than half of a height of the channel layer in the film thickness direction, forming a gate layer above the second insulative layer, the gate layer having a height in the film thickness direction that is less than the height of the channel layer in the film thickness direction, and forming an electrode layer directly above the channel layer to form a nanowire. Sides of the electrode layer extend beyond sides of the channel layer in an element thickness direction perpendicular to the film thickness direction.

In accordance with another general embodiment, an apparatus includes a channel layer positioned above a substrate in a film thickness direction, the channel layer including a lower channel layer positioned below an upper channel layer in the film thickness direction, a gate dielectric layer positioned on sides of the channel layer, a gate layer positioned on sides of the gate dielectric layer, and an electrode layer positioned above an upper portion of the channel layer in the film thickness direction. Sides of the electrode layer extend beyond sides of the channel layer in an element thickness direction perpendicular to the film thickness direction.

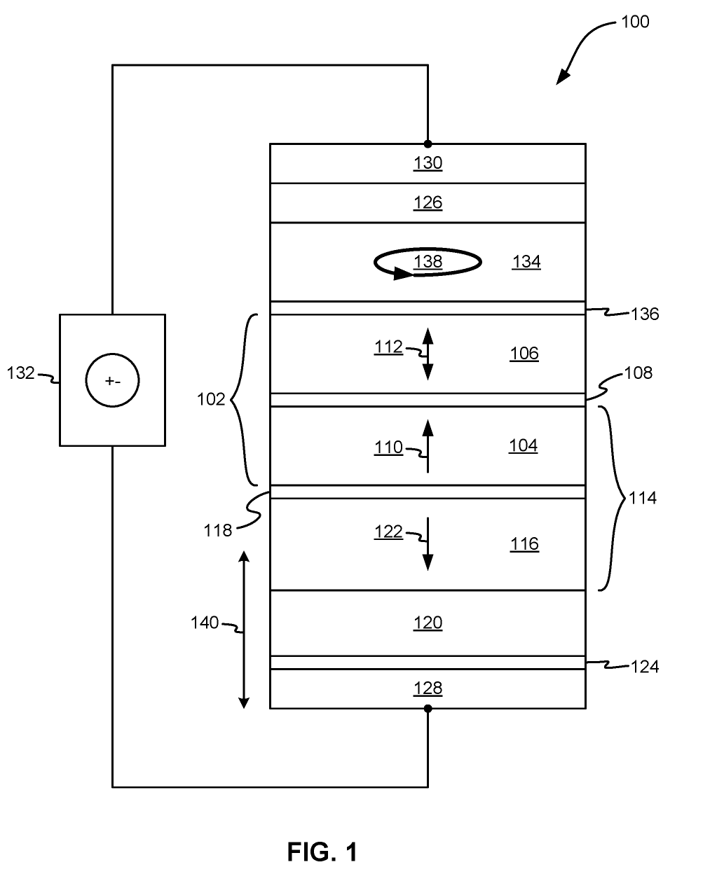

Referring to FIG. 1, a magnetic memory element 100 is shown according to one embodiment. The memory element 100 may be used in a perpendicular magnetic tunnel junction (pMTJ) memory element, as described in various embodiments herein. The memory element 100 may include a magnetic tunnel junction (MTJ) 102 that may include a magnetic reference layer 104, a magnetic free layer 106, and a thin, non-magnetic, electrically-insulating magnetic barrier layer 108 positioned between the reference layer 104 and the free layer 106 in a film thickness direction 140. The barrier layer 108 may include an oxide, such as MgO, Al₂O₃, etc., or some other suitable material known in the art. The reference layer 104 has a magnetization 110 that is fixed in a direction that is perpendicular to a horizontal plane of the layer, as indicated by the arrow. The horizontal plane is sometimes referred to as a plane of formation in the embodiments described herein. The free layer 106 has a magnetization 112 that may be in either of two directions perpendicular to a horizontal plane of the free layer 106, as indicated by the two arrows. While the magnetization 112 of the free layer 106 remains in either of two directions perpendicular to the plane of the free layer 106 in a quiescent state, it may be selectable switched between these two directions, as is described in greater detail herein. When the magnetization 112 of the free layer 106 is in the same direction as the magnetization 110 of the reference layer 104, the electrical resistance across the MTJ 102 is at a low resistance state. Conversely, when the magnetization 112 of the free layer 106 is opposite to the magnetization 110 of the reference layer 104, the electrical resistance across the MTJ 102 is in a high resistance state.

The reference layer 104 may be part of an anti-parallel magnetic pinning structure 114 that may include a magnetic pinned layer 116 and a non-magnetic, antiparallel coupling layer 118 positioned between the pinned layer 116 and the reference layer 104 in the film thickness direction 140. The antiparallel coupling layer 118 may comprise any suitable material known in the art, such as Ru, and may be constructed to have a thickness that causes ferromagnetic antiparallel coupling of the pinned layer 116 and the reference layer 104.

In one approach, the pinned layer 116 may be exchange coupled with an antiferromagnetic layer 120, which may comprise any suitable material known in the art, such as IrMn. Exchange coupling between the antiferromagnetic layer 120 and the pinned layer 116 strongly pins the magnetization 122 of the pinned layer 116 in a first direction. The antiparallel coupling between the pinned layer 116 and the reference layer 104 pins the magnetization 110 of the reference layer 104 in a second direction opposite to the direction of magnetization 122 of the pinned layer 116.

According to one approach, a seed layer 124 may be positioned below the pinned layer 116 in the film thickness direction 140 to initiate a desired crystalline structure in the layers deposited thereabove.

In another approach, a capping layer 126 may be positioned above the free layer 106 to protect the underlying layers during manufacture, such as during high temperature annealing.

A lower electrode 128 and an upper electrode 130 may be positioned near a bottom and a top of the memory element 100, respectively, in one approach. The lower electrode 128 and the upper electrode 130 may be constructed of a non-magnetic, electrically conductive material of a type known in the art, such as Ru, Au, Ag, Cu, etc., and may provide an electrical connection with a circuit 132. The circuit 132 may include a current source, and may further include circuitry for reading an electrical resistance across the memory element 100.

The magnetic free layer 106 has a magnetic anisotropy that causes the magnetization 112 of the free layer 106 to remain stable in one of two directions perpendicular to the horizontal plane of the free layer 106. In a write mode of use for the memory element 100, the orientation of the magnetization 112 of the free layer 106 may be switched between these two directions by applying an electrical current through the memory element 100 via the circuit 132. A current in a first direction causes the magnetization 112 of the free layer 106 of the memory element 100 to flip to a first orientation, and a current in a second direction opposite to the first direction causes the magnetization 112 of the free layer 106 of the memory element 100 to flip to a second, opposite direction.

For example, if the magnetization 112 is initially oriented in an upward direction in FIG. 1, applying a current in a downward direction through the memory element 100 causes electrons to flow in an opposite direction upward through the memory element 100. Electrons travelling through the reference layer 104 become spin polarized as a result of the magnetization 110 of the reference layer 104. These spin-polarized electrons cause a spin torque on the magnetization 112 of the free layer 106, which causes the magnetization 112 to flip directions, from the upward direction to a downward direction.

On the other hand, if the magnetization 112 of the free layer 106 is initially in a downward direction in FIG. 1, applying an electrical current through the memory element 100 in an upward direction in FIG. 1 causes electrons to flow in an opposite direction, downward through the memory element 100. However, because the magnetization 112 of the free layer 106 is opposite to the magnetization 110 of the reference layer 104, the electrons will not be able to pass through the barrier layer 108. As a result, the electrons (which have been spin polarized by the magnetization 112 of the free layer 106) will accumulate at the junction between the free layer 106 and the barrier layer 108. This accumulation of spin polarized electrons causes a spin torque that causes the magnetization 112 of the free layer 106 to flip from the downward direction to an upward direction.

In order to assist the switching of the magnetization 112 of the free layer 106, the memory element 100 may include a spin polarization layer 134 positioned above the free layer 106. The spin polarization layer 134 may be separated from the free layer 106 by an exchange coupling layer 136. The spin polarization layer 134 has a magnetic anisotropy that causes it to have a magnetization 138 with a primary component oriented in the in plane direction (e.g., perpendicular to the magnetization 112 of the free layer and the magnetization 110 of the reference layer 104). The magnetization 138 of the spin polarization layer 134 may be fixed in one approach, or may move in a precessional manner as shown in FIG. 1. The magnetization 138 of the spin polarization layer 134 causes a spin torque on the free layer 106 that assists in moving its magnetization 112 away from its quiescent state perpendicular to the plane of the free layer 106. This allows the magnetization 112 of the free layer 106 to more easily flip with less energy being utilized to flip the magnetization 112 in response to applying a write current to the memory element 100.

The memory element 100 described in FIG. 1 is intended to provide context to the various embodiments described herein. The structures and methods described herein in accordance with various embodiments may comprise a portion of the memory element 100 described in FIG. 1 and/or used in conjunction with the memory element 100, in various approaches.

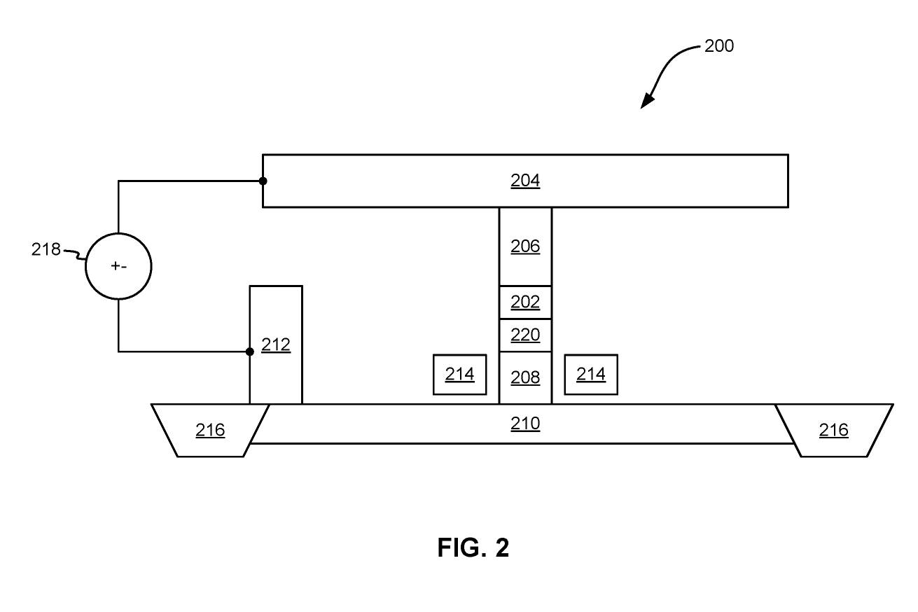

Now referring to FIG. 2, a portion of a magnetic random access memory (MRAM) structure 200 that includes a magnetoresistive sensor 202 is shown according to one embodiment. The MRAM structure 200 may be operated and utilized as understood by those of skill in the art, with any special use cases being specified in accordance with an embodiment herein. The memory element 100 described in FIG. 1 may be used as the magnetoresistive sensor 202 of FIG. 2 in accordance with embodiments that store data in MRAM. In one embodiment, an MTJ element may be used as the magnetoresistive sensor 202.

The MRAM structure 200 includes a bit line 204 that supplies current across the magnetoresistive sensor 202 from a voltage source 218. The bit line 204 may comprise any suitable material known in the art, such as TaN, W, TiN, Au, Ag, Cu, etc. An extension layer 206 electrically couples the magnetoresistive sensor 202 with the bit line 204. The extension layer 206 may comprise any suitable material known in the art, such as Ru, Ta, etc. A source terminal 220 is coupled between the magnetoresistive sensor 202 and a channel layer 208, which is in electrical contact with a n+ source layer 210. The channel layer 208 may comprise any suitable semiconductor material known in the art, such as Si, Ge, GaAs-compounds, etc. The n+ source layer 210 may comprise any suitable material known in the art, such as TaN, W, TiN, Au. Ag, Cu, etc., and is electrically coupled to the voltage source 218 via a source line 212, which may comprise any suitable material known in the art, such as TaN, W, TiN, Au, Ag, Cu, etc. Positioned across the channel layer 208 is a word line 214 which may comprise any suitable material known in the art, such as TaN, W, TiN, Au, Ag, Cu, etc. On either side of the n+source layer 210 are shallow trench isolation (STI) layers 216 which provide electrical insulation between an adjacent n+source layer 210. Moreover, although not specifically shown, electrically insulative material may be positioned around the various layers shown in FIG. 2, as would be understood by one of skill in the art.

Silicon channels that are used to connect conventional MTJs show low field effect mobility compared to III-V semiconductor channels which are constructed of materials such as InGaAs, InAs, etc. The current used during operation of a pMTJ is greater than that used by a typical MTJ during operation. Therefore, a silicon channel semiconductor, which is typically used to deliver voltage to a MTJ is not able to handle the current load of a pMTJ during write operation, e.g., 6-10 mega-ampere per square centimeter (MA/cm²), when a silicon channel is configured to have a minimum size allowed in certain complementary metal-oxide-semiconductor (CMOS) technologies. Therefore, it is desirable to utilize a compound semiconductor channel as an access transistor for a pMTJ memory array. Methods of manufacturing such a compound semiconductor channel (vertical III-V semiconductor channel for use with a pMTJ) are described herein in accordance with several embodiments, along with the structures themselves.

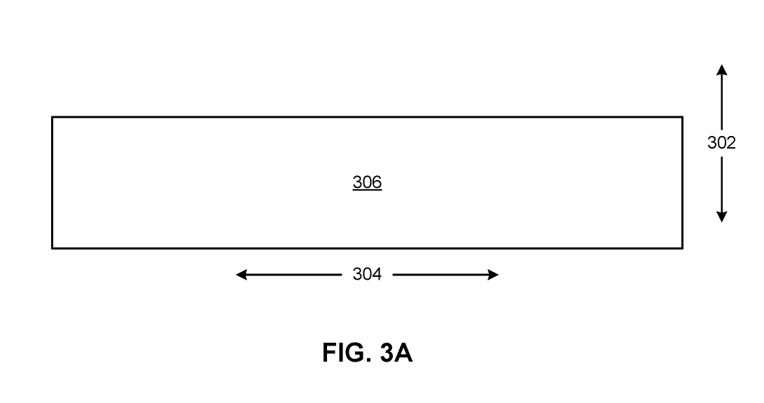

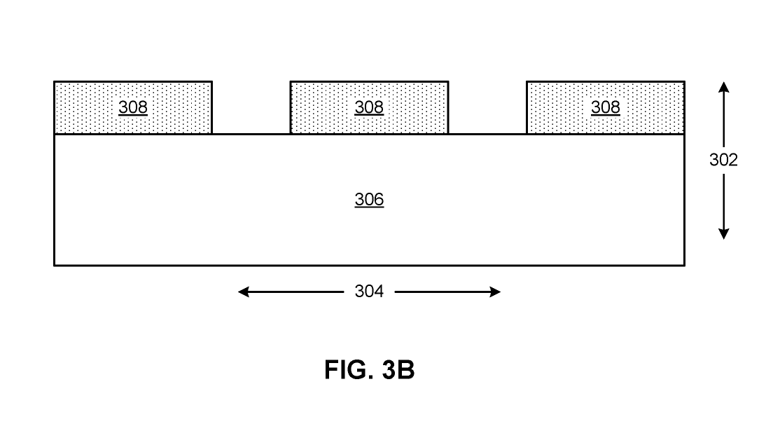

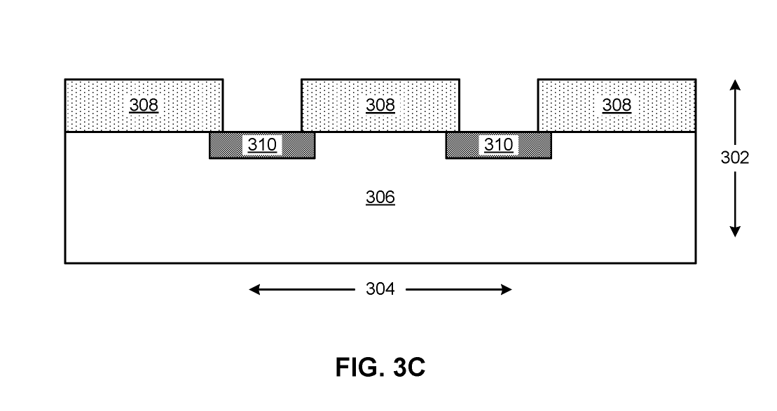

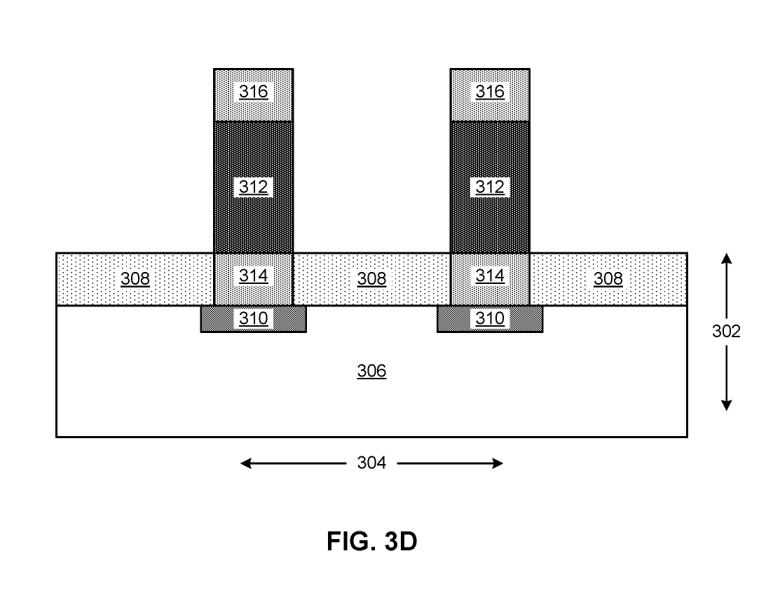

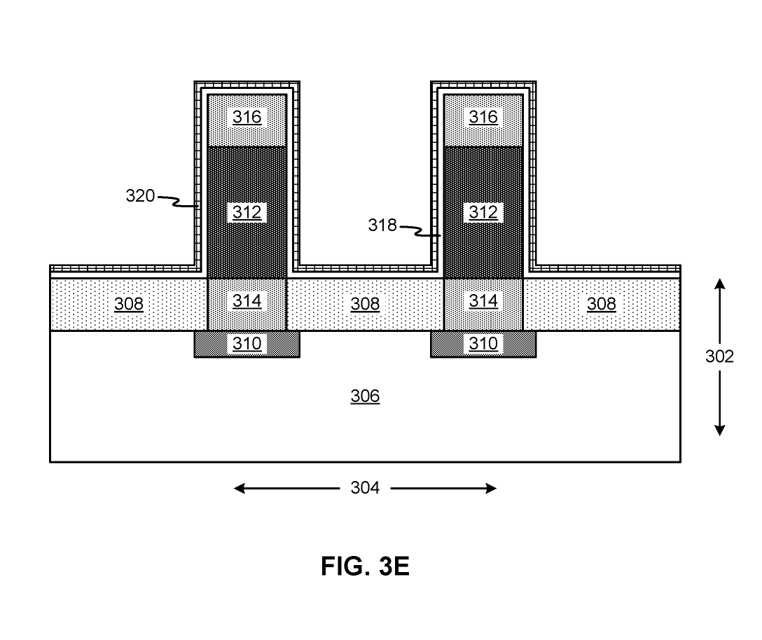

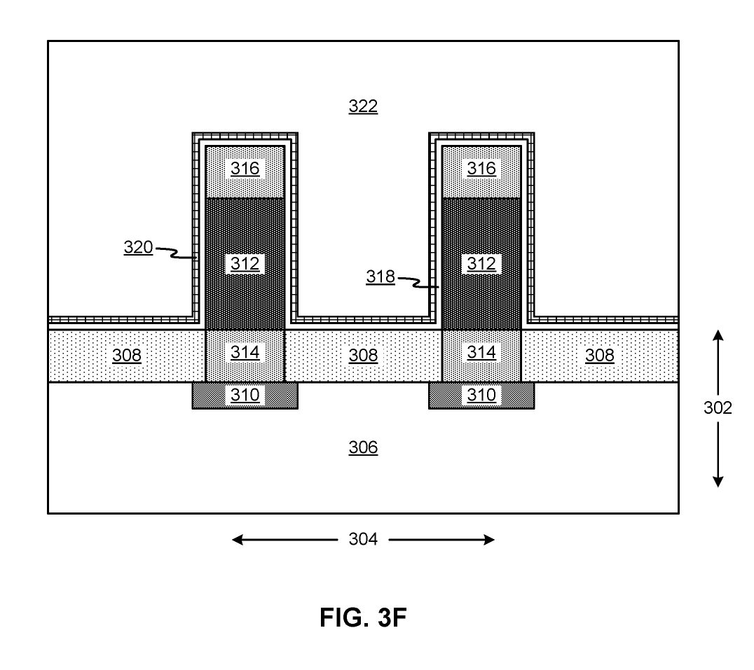

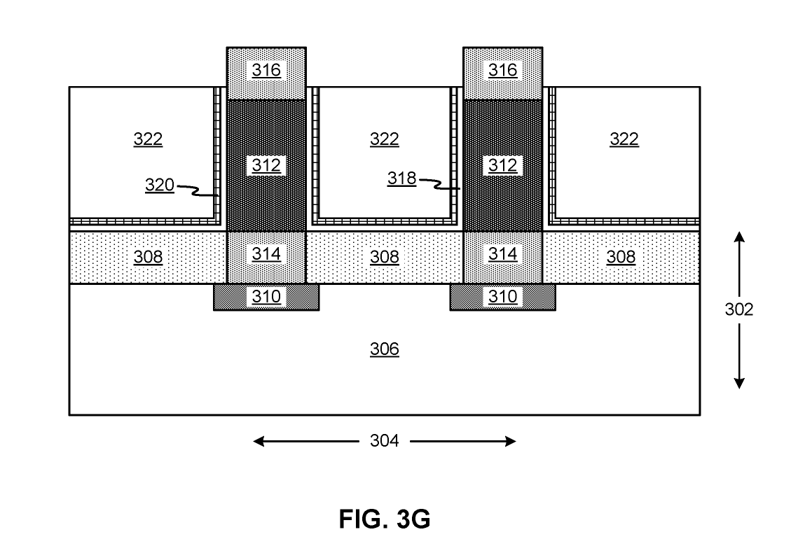

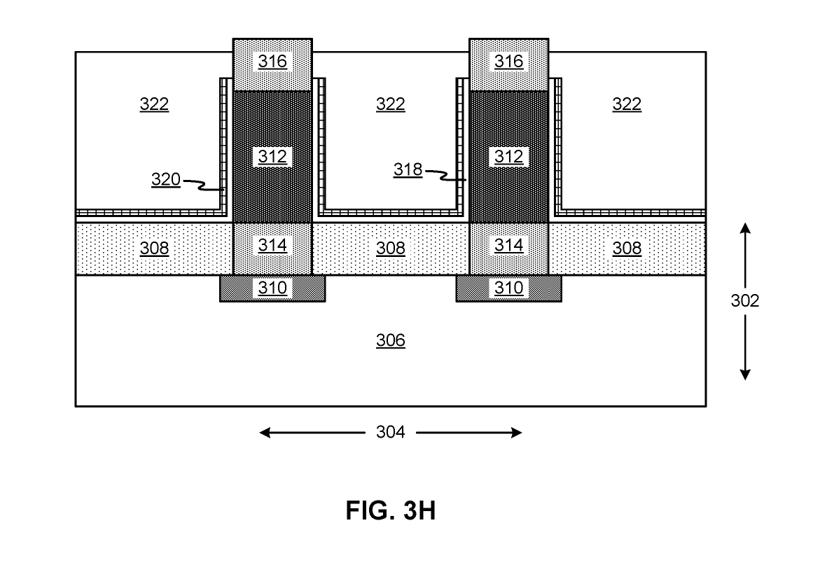

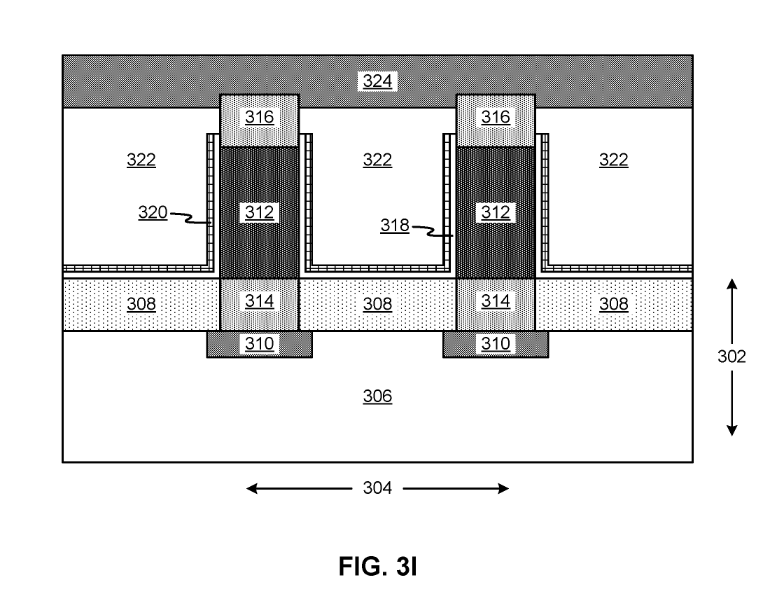

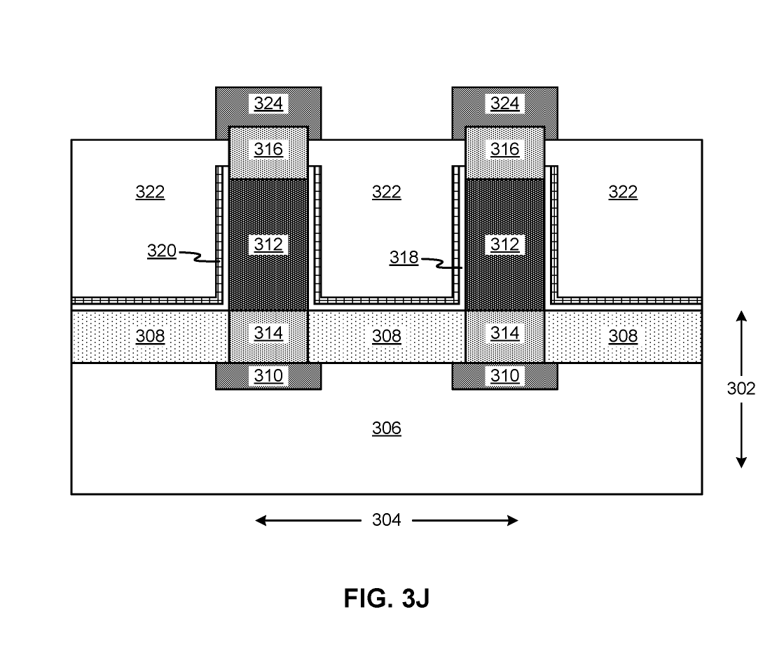

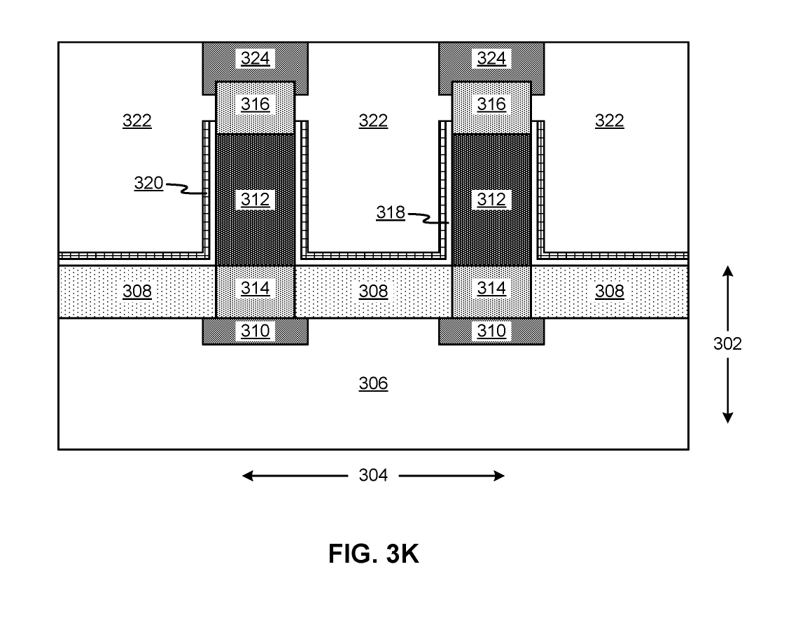

Now referring to FIGS. 3A-3K, formation of a silicon channel structure is shown according to one embodiment. The silicon channel structure may be formed in accordance with the present invention in any of the environments depicted herein, among others not specifically described, in various approaches. Of course, more steps, layers, and/or structures may be utilized in the formation of any of the structures and/or layers thereof than those specifically described in FIGS. 3A-3K, as would be understood by one of skill in the art upon reading the present descriptions.

Each of the intermediate structures shown in FIGS. 3A-3K may be formed by any suitable component of the operating environment. For example, in various embodiments, the structure(s) may be partially or entirely formed by a machine, controller, processing circuit, or some other device or combination of devices suitable for manufacturing and/or processing a thin film structure. A processing circuit may include one or more processors, chips, and/or modules implemented in hardware and/or software, and preferably having at least one hardware component, and may be utilized in any device to form one or more structures or layer thereof. Illustrative processing circuits include, but are not limited to, a CPU, an ASIC, a FPGA, etc., combinations thereof, or any other suitable computing device known in the art.

In the descriptions of FIGS. 3A-3K, each layer may be formed using any known deposition process, such as sputtering, plating, chemical vapor deposition (CVD), plasma chemical vapor deposition (pCVD), physical vapor deposition (PVD), molecular beam epitaxy (MBE), atomic layer deposition (ALD), etc. Moreover, any descriptions of removal of layers and/or material may be performed using any material removal process of a type known in the art, such as planarization, chemical mechanical polishing (CMP), recess etching, reactive ion etching (RIE), ion milling, plasma etching, photolithography, etc.

As shown in FIG. 3A, a substrate 306 is formed, having a desired thickness in a film thickness direction 302 and a desired width in an element width direction 304 which is perpendicular to the film thickness direction 302. Moreover, although not specifically shown, the substrate 306 (and layers formed thereon) also have a depth in a z-direction into the page that is along a plane normal to both the film thickness direction 302 and the element width direction 304.

The substrate 306 may comprise any suitable material known in the art. For the descriptions included below, the substrate 306 comprises Si, and more specifically, Si oriented in the (111) direction, e.g., Si(111).

As shown in FIG. 3B, mask layer 308 is formed above the substrate 306 in the film thickness direction 302. After formation of the mask layer 308, grooves are formed therethrough which expose portions of the substrate 306 therebelow in a desired pattern. In one embodiment, a single groove is formed, although in FIG. 3B-3K, two grooves are shown. Any number of grooves may be formed based on the patterning of the mask layer 308, as would be understood by one of skill in the art. The exposed portions of the substrate 306 each have a predetermined size that is consistent with a desired thickness or gauge of a nanowire that will be constructed thereon.

The mask layer 308 may comprise any suitable material known in the art, such as SiO₂, SiON, ZrO₂, HfO₂, Al₂O₃, etc. In one embodiment, the mask layer 308 comprises SiO₂.

Now referring to FIG. 3C, portions 310 of the substrate 306 below the grooves (e.g., exposed by the grooves through the mask layer 308) are doped with one or more elements. In one embodiment, the exposed portions 310 of the substrate 306 are doped to transform Si(111) into a (111)B orientation via V-incorporated Si³⁺ and/or III-terminated Si¹⁺.

With reference to FIG. 3D, channel layers 312 are formed above the doped portions 310 of the substrate 306. Each channel layer 312 extends beyond the mask layer 308 in the film thickness direction 302, and the height of these channel layers 312 may be configured to coincide with a dimension on which a nanowire is desired for coupling electronic elements together, as would be understood by one of skill in the art. In one embodiment, the channel layers 312 may comprise InGaAs, or some other suitable material known in the art.

In one embodiment, during formation of the channel layers 312, a lower portion 314 of each channel layer 312 may be in-situ doped with Si to form Si-doped InGaAs. The lower portion 314 is positioned on an end of the channel layer 312 that is closest to the substrate 306. Moreover, an upper portion 316 of the channel layer may be doped with Si to form Si-doped InGaAs. The upper portion 316 is positioned on an end of the channel layer 312 that is opposite the lower portion 314.

Now referring to FIG. 3E, an insulative layer 318 (also referred to as a gate dielectric layer) is formed above each channel layer 312 (including the upper portion 316 thereof) and the mask layer 308 in the film thickness direction 302. Moreover, the insulative layer 318 is formed on sides of the channel layer 312 (including the upper portion 316 thereof). In one embodiment, the insulative layer 318 may be formed full film, covering an entirety of the exposed surfaces of the structure at this point. After formation of the insulative layer 318, a gate layer 320 is formed above the insulative layer 318 in the film thickness direction 302 (which may be formed full film like the insulative layer 318 in one embodiment).

In various embodiments, the gate layer 320 may comprise doped polysilicon, W, TaN, TiNi, TiN, other suitable materials known in the art, and/or combinations thereof.

As shown in FIG. 3F, a second insulative layer 322 is formed above the gate layer 320 in the film thickness direction 302. This second insulative layer 322 may comprise any suitable material known in the art, such as SiO₂, SiON, ZrO₂, HfO₂, Al₂O₃, etc. In one embodiment, the second insulative layer 322 comprises a dielectric material. The second insulative layer 322 is formed such that an upper extent thereof is higher than an upper extent of the gate layer 320.

With reference to FIG. 3G, portions of the insulative layer 318, the gate layer 320, and the second insulative layer 322 are removed to expose the upper portion 316 of each channel layer. Any known removal technique may be used, such as etching in one embodiment. The height to which the removal is performed will dictate how far up the sides of the channel layers 312 the gate layers 320 are positioned.

After this material removal process, more insulative material is deposited above the structure, planarized, and then etched back as shown in FIG. 3H to reveal the upper surface of the upper portion 316 of each channel layer.

As shown in FIG. 3I, an electrode layer 324 is formed above the upper portion 316 of each channel layer 312 (including the upper portion 316) and the second insulative layer 322 in the film thickness direction 302. Sides of the electrode layers 324 extend beyond sides of the channel layers 312 in an element width direction 304 perpendicular to the film thickness direction 302 (and possibly in the depth direction normal to the element width direction 304 and the film thickness direction 302).

In various embodiments, the electrode layer 324 may comprise doped polysilicon, W, TaN, TiNi, TiN, other suitable materials known in the art, and/or combinations thereof.

After forming the electrode layer 324 full film, portions of the electrode layer 324 that are not positioned above the channel layers 312 are removed, while maintaining some overlap of sides of the electrode layers 324 beyond extents of each channel layer 312 in the element width direction 304 and the depth direction, as shown in FIG. 3J.

After the portions of the electrode layers 324 are removed, a third insulative layer is formed above and grows the second insulative layer 322. The third insulative layer is formed above the entire structure, and then the structure is planarized to a height of the upper surface of the electrodes 324. This exposes the upper surfaces of the electrode layers 324, allowing electrical contact to be made thereto. This structure, as shown in FIG. 3K, comprises two nanowires configured to electrically couple to any desired electrical element.

In one embodiment, a pMTJ may be formed above one or both of the electrode layers 324 in the film thickness direction 302. In this embodiment, at least one of the nanowires is electrically coupled to the pMTJ. In one further embodiment, a pMTJ may comprise a seed layer, an underlayer positioned above the seed layer, a synthetic antiferromagnetic (SAF) seed layer positioned above the underlayer, a first SAF layer positioned above the SAF seed layer, a spacer layer positioned above the first SAF layer, an antiferromagnetic (AFM) coupling layer positioned above the spacer layer, a second SAF layer positioned above the AFM coupling layer, a ferromagnetic (FM) coupling layer positioned above the second SAF layer, a reference layer that comprises a first reference layer positioned below a second reference layer, a barrier layer positioned above the reference layer, a free layer which includes a lower free layer positioned above the barrier layer, a middle free layer positioned above the lower free layer, and an upper free layer positioned above the middle free layer. The pMTJ may also comprise a first cap layer positioned above the upper free layer, a second cap layer positioned above the first cap layer, a third cap layer positioned above the second cap layer, and a fourth cap layer positioned above the third cap layer.

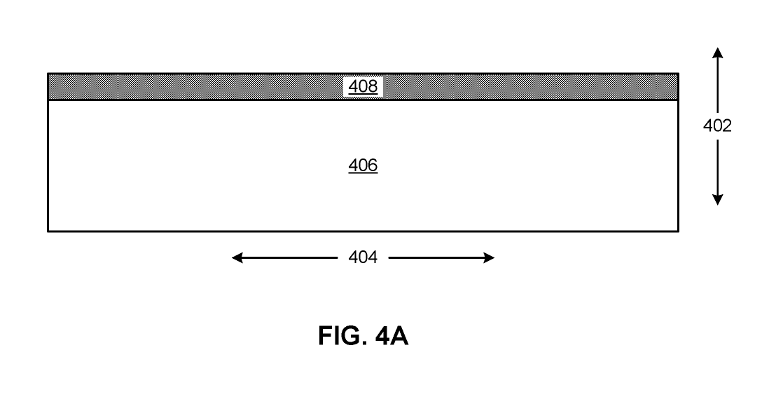

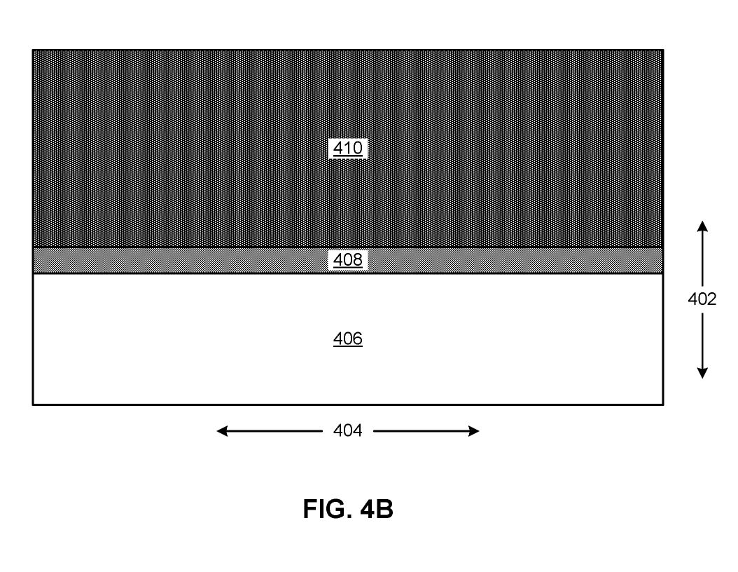

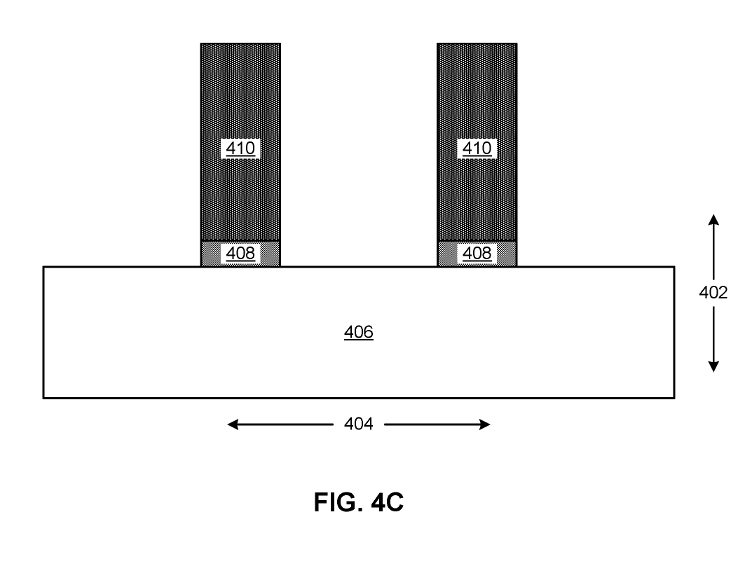

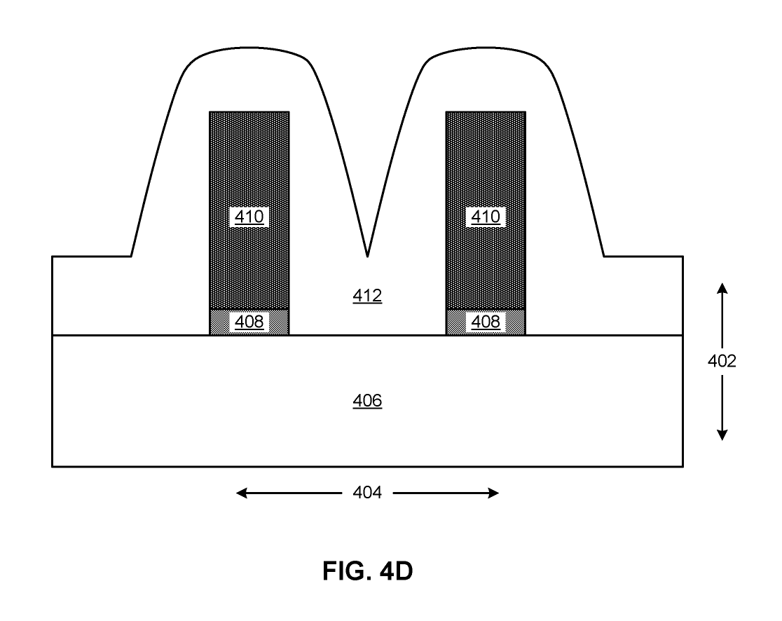

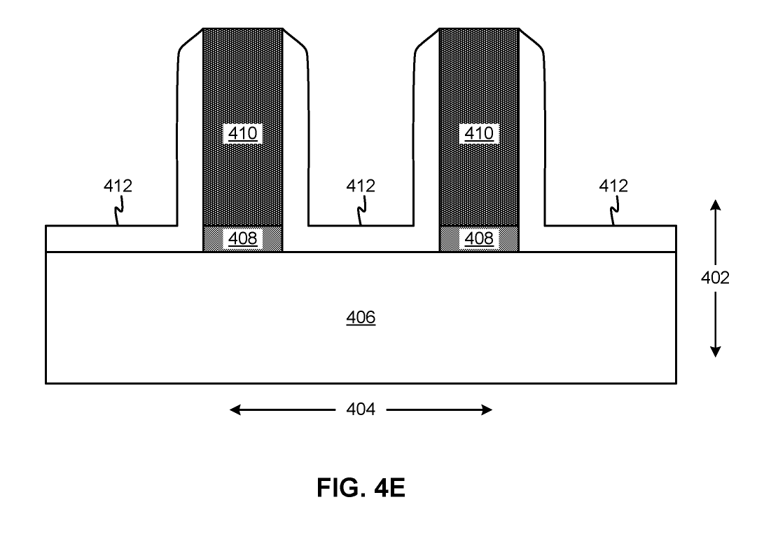

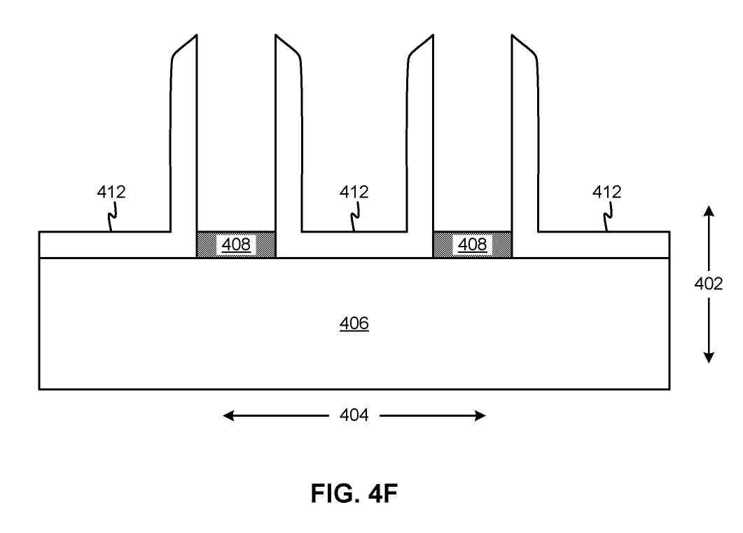

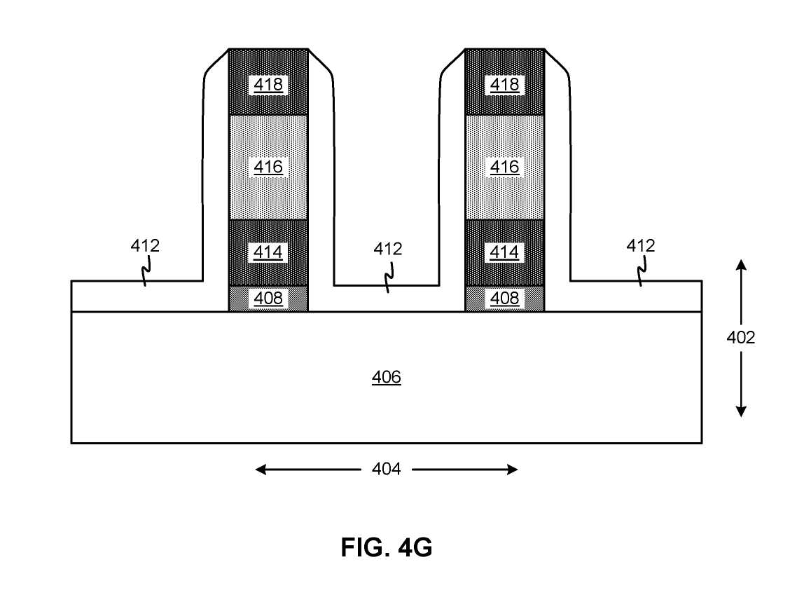

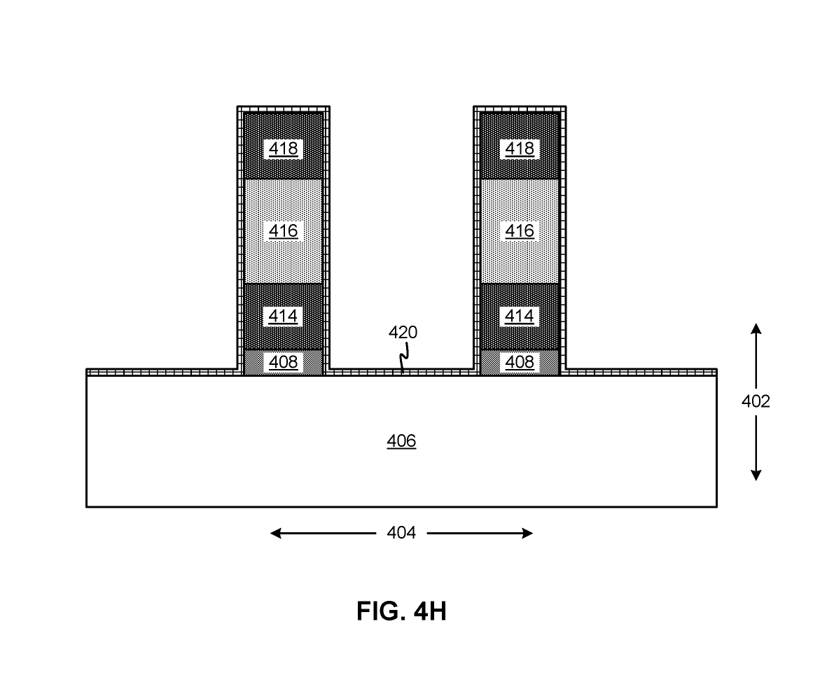

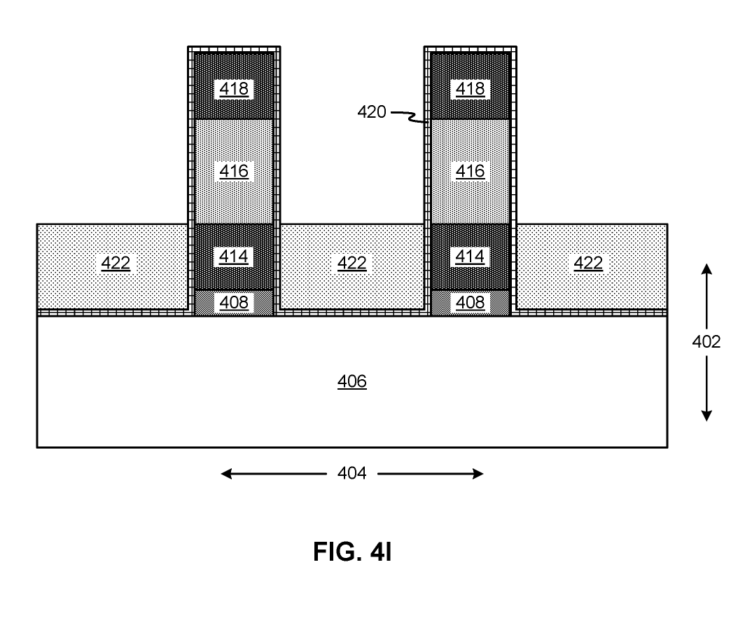

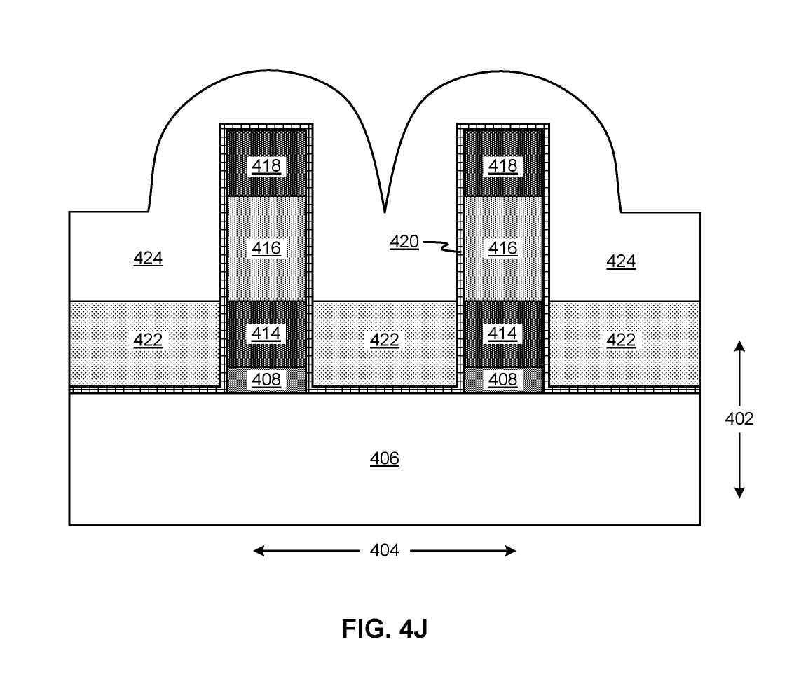

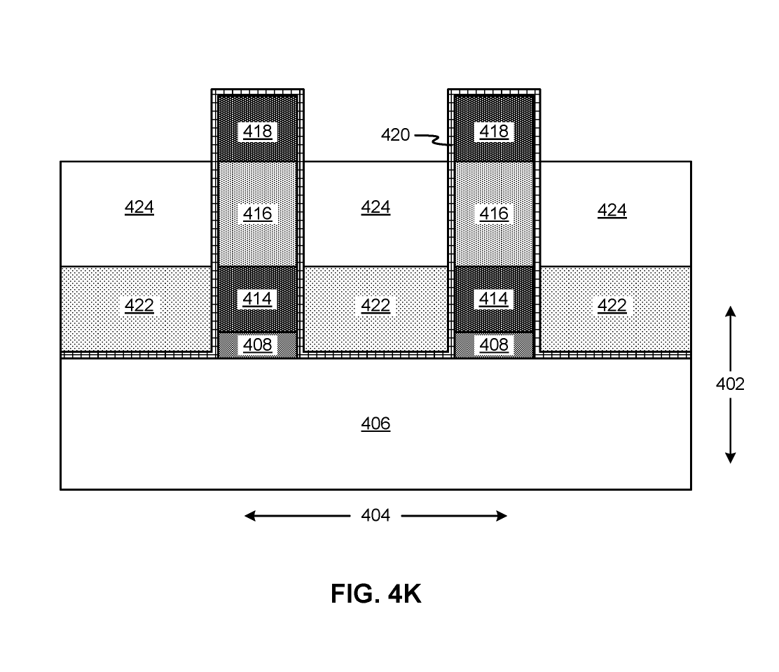

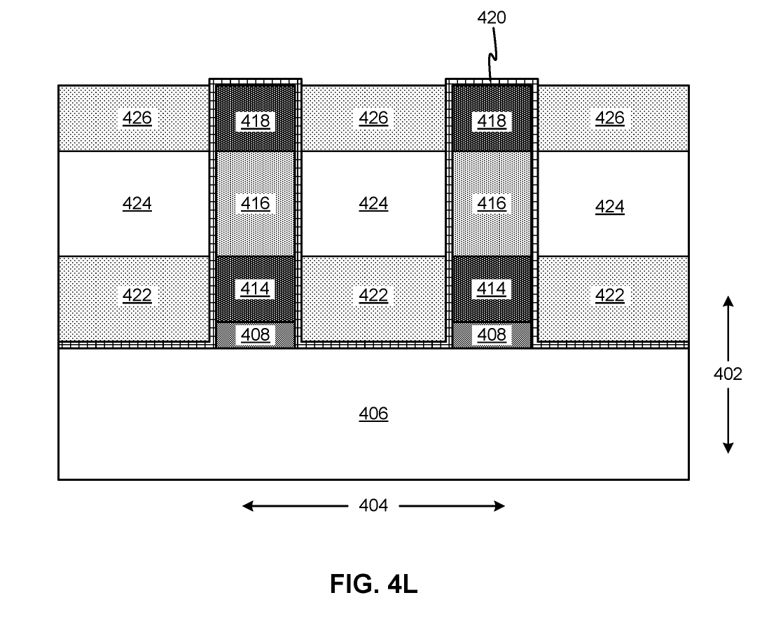

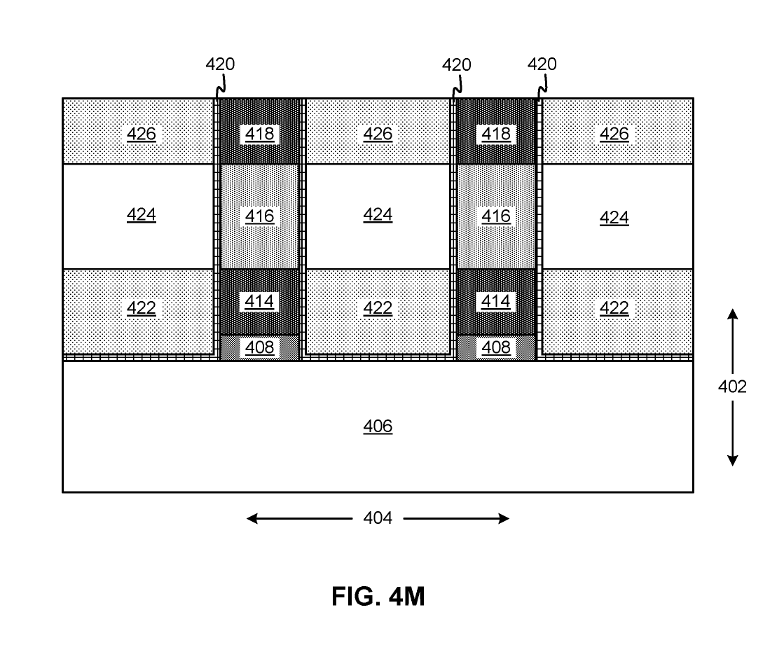

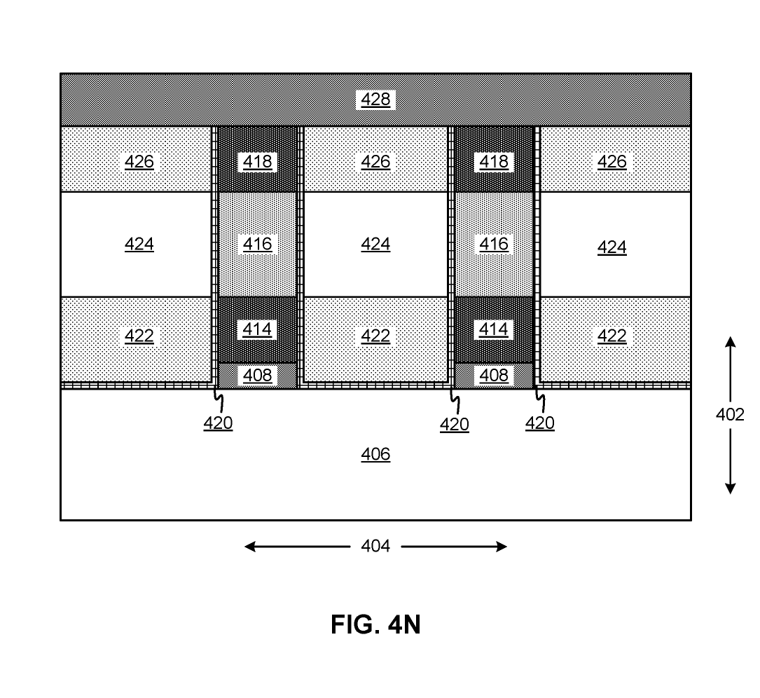

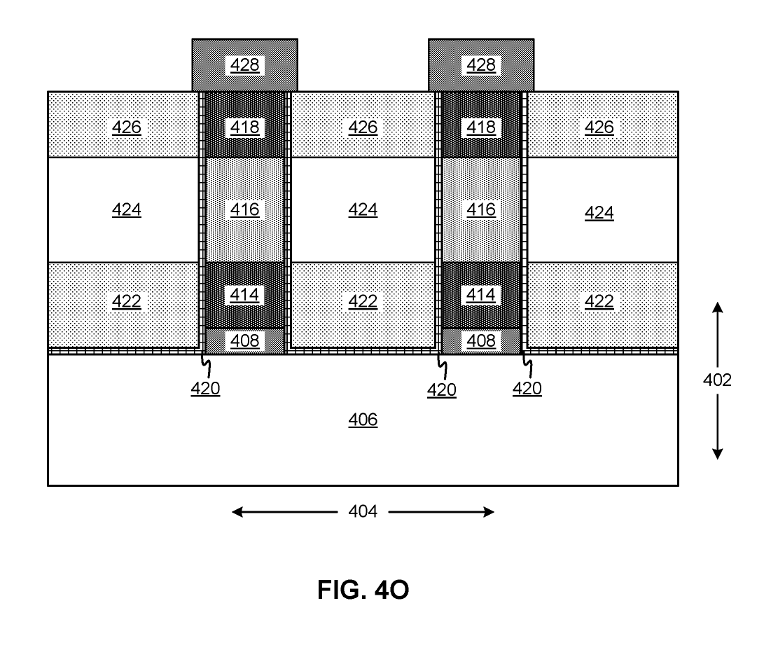

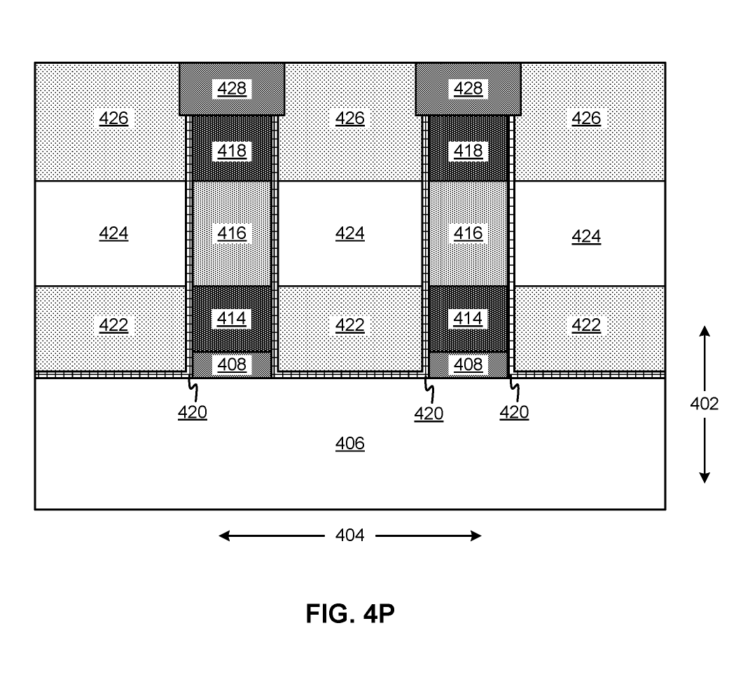

Now referring to FIGS. 4A-4P, formation of a silicon channel structure is shown according to one embodiment. The silicon channel structure may be formed in accordance with the present invention in any of the environments depicted herein, among others not specifically described, in various approaches. Of course, more steps, layers, and/or structures may be utilized in the formation of any of the structures and/or layers thereof than those specifically described in FIGS. 4A-4P, as would be understood by one of skill in the art upon reading the present descriptions.

Each of the intermediate structures shown in FIGS. 4A-4P may be formed by any suitable component of the operating environment. For example, in various embodiments, the structure(s) may be partially or entirely formed by a machine, controller, processing circuit, or some other device or combination of devices suitable for manufacturing and/or processing a thin film structure. A processing circuit may include one or more processors, chips, and/or modules implemented in hardware and/or software, and preferably having at least one hardware component, and may be utilized in any device to form one or more structures or layer thereof. Illustrative processing circuits include, but are not limited to, a CPU, an ASIC, a FPGA, etc., combinations thereof, or any other suitable computing device known in the art.

In the descriptions of FIGS. 4A-4P, each layer may be formed using any known deposition process, such as sputtering, plating, CVD, pCVD, PVD, MBE, ALD, etc. Moreover, any descriptions of removal of layers and/or material may be performed using any material removal process of a type known in the art, such as planarization, CMP, recess etching, RIE, ion milling, plasma etching, photolithography, etc.

As shown in FIG. 4A, a substrate 406 is formed, along with an etch-stop layer 408 thereon in a film thickness direction 402. The substrate 406 is formed to a desired thickness in the film thickness direction 402 and a desired width in an element width direction 404 which is perpendicular to the film thickness direction 402. Moreover, although not specifically shown, the substrate 406 (and layers formed thereon) also have a depth in a z-direction into the page that is along a plane normal to both the film thickness direction 402 and the element width direction 404.

The substrate 406 may comprise any suitable material known in the art. For the descriptions included below, the substrate 406 comprises Si, and more specifically, Si oriented in the (111) direction, e.g., Si(111).

The etch-stop layer 408 may comprise doped-Si, in one embodiment, or some other suitable material known in the art which is resistant to certain material removal processes.

As shown in FIG. 4B, a sacrificial layer 410 is formed above the etch-stop layer 408 in the film thickness direction 402. The sacrificial layer 410 may comprise any suitable material to be easily removed later, such as amorphous Si (a-Si) in one embodiment.

With reference to FIG. 4C, portions of the sacrificial layer 410 and the etch-stop layer 408 are removed to form a pillar having a predetermined size (thickness, depth, and width). As shown in FIGS. 4C-4P, two pillars are formed, but any number may be formed simultaneously using the methods described herein, from one to thousands.

In FIG. 4D, formation in the film thickness direction 402 of an insulative layer 412 above the pillars and exposed portions of the substrate 406 that are not covered by the pillars is shown. The insulative layer 412 may comprise any suitable material, such as a dielectric in one embodiment.

As shown in FIG. 4E, portions of the insulative layer 412 are removed to thin the insulative layer 412 in the film thickness direction 402 and expose upper surfaces of the pillars (e.g., upper surfaces of the sacrificial layers 410).

Next, all remaining portions of the sacrificial layers 410 are removed to form channel molds, as shown in FIG. 4F. Thereafter, channel layers 416 are formed above the etch-stop layer 408 within the channel molds, as shown in FIG. 4G. Each channel layer 416 extends to a height of the channel mold in the film thickness direction 402.

In one embodiment, the channel layers 416 may comprise InGaAs, or some other similar material.

In another embodiment, during formation of the channel layers 416, lower portions 414 of each channel layer 416 may be in-situ doped with Si to form Si-doped InGaAs. The lower portions 414 are positioned on an end of each channel layer 416 that is closest to the substrate 406. Moreover, upper portions 418 of the channel layers 416 may be doped with Si to form Si-doped InGaAs. The upper portions 418 are positioned on an end of each channel layer 416 that is opposite the lower portion 414.

Thereafter, the channel mold is removed, as shown in FIG. 4H, and a gate dielectric layer 420 is formed above the substrate 406 and the channel layers 416 (including the upper portion 418 thereof) in the film thickness direction 402, and along sides of the etch-stop layers 408 and the channel layers 416 (including the lower portion 414 and upper portion 418 thereof). The gate dielectric layer 420 may comprise any suitable dielectric material, such as SiO₂, SiON, ZrO₂, HfO₂, Al₂O₃, etc.

As shown in FIG. 4I, a second insulative layer 422 is formed above portions of the gate dielectric layer 420 that are positioned directly above the substrate 406. The second insulative layer 422 has a height in the film thickness direction 402 less than half of a height of the channel layer 416 (including the upper portion 418 thereof) in the film thickness direction 402. In one embodiment, a height of the second insulative layer 422 may be about equal to a height of the lower portions 414 of the channel layers.

Now referring to FIG. 4J, a gate layer 424 is formed above the second insulative layer 422. The gate layer 424 has a height in the film thickness direction 402 that is less than the height of the channel layer 416 (including the upper portion 418 thereof) in the film thickness direction 402, after planarization of the gate layer 424 as shown in FIG. 4K.

With reference to FIG. 4L, a third insulative layer 426 is formed above the second insulative layer 422, with the third insulative layer 426 having a height about equal to an upper surface of the upper portions 418 of the channel layers, in one approach. This particular height may be achieved by forming the third insulative layer 426 full film, and then planarizing the structure to reduce the thickness of the third insulative layer 426 to a desired height.

As shown in FIG. 4M, portions of the third insulative layer 426 and the gate dielectric layer 420 are removed to expose an upper surface of each channel layer 416 (e.g., an upper surface of the upper portion 418 thereof). Then, the third insulative layer 426 and the upper surface of the channel layers 416 (e.g., an upper surface of the upper portion 418 thereof) are planarized.

As shown in FIG. 4N, an electrode layer 428 is formed directly above each channel layer 416 (e.g., an upper surface of the upper portion 418 thereof). The electrode layer 428 may be formed full film, in one approach. Moreover, the electrode layer 428 may comprise doped polysilicon, W, TaN, TiNi, TiN, other suitable materials known in the art, and/or combinations thereof.

The electrode layer 428 then undergoes a material removal process to define a size of each electrode layer 428 above its respective pillar, as shown in FIG. 40. Sides of each electrode layer 428 extend beyond sides of a corresponding channel layer 416 in an element thickness direction 404 perpendicular to the film thickness direction 402 (and possibly in the depth direction).

As shown in FIG. 4P, more insulative material is deposited on the structure to grow the third insulative layer 426, then planarized, to form the structure having insulative layers 426 422, that sandwich the gate layer 424. This creates a set of nanowires. This structure, as shown in FIG. 4P, comprises two nanowires configured to electrically couple to any desired electrical element.

In one embodiment, a pMTJ may be formed above one or both of the electrode layers 428 in the film thickness direction 402. In this embodiment, at least one of the nanowires is electrically coupled to the pMTJ. In a further embodiment, a pMTJ may comprise a seed layer, an underlayer positioned above the seed layer, a synthetic antiferromagnetic (SAF) seed layer positioned above the underlayer, a first SAF layer positioned above the SAF seed layer, a spacer layer positioned above the first SAF layer, an antiferromagnetic (AFM) coupling layer positioned above the spacer layer, a second SAF layer positioned above the AFM coupling layer, a ferromagnetic (FM) coupling layer positioned above the second SAF layer, a reference layer that comprises a first reference layer positioned below a second reference layer, a barrier layer positioned above the reference layer, a free layer which includes a lower free layer positioned above the barrier layer, a middle free layer positioned above the lower free layer, and an upper free layer positioned above the middle free layer. The pMTJ may also comprise a first cap layer positioned above the upper free layer, a second cap layer positioned above the first cap layer, a third cap layer positioned above the second cap layer, and a fourth cap layer positioned above the third cap layer.

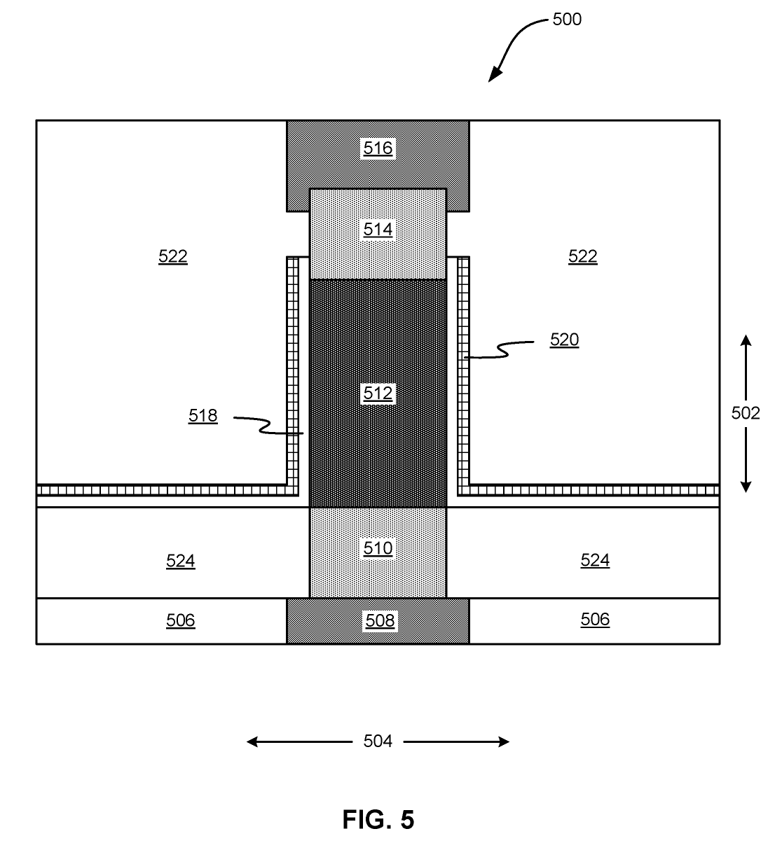

With reference to FIG. 5, a vertical compound semiconductor 500 is shown according to one embodiment. As shown, the vertical compound semiconductor 500 comprises a channel layer 512 positioned above a substrate 506 in a film thickness direction 502. The channel layer 512 includes a lower channel layer 510 positioned below an upper channel layer 514 in the film thickness direction 502. Moreover, a portion of the substrate positioned directly below and in direct contact with the channel layer 512 (e.g., the lower channel layer 510 thereof) may include Si(111)B, while the substrate comprises Si(111).

In addition, the vertical compound semiconductor 500 comprises a gate dielectric layer 518 positioned on sides of the channel layer 512 (including at least some of the upper channel layer 514 in some approaches) and along an upper surface of a dielectric layer 524. A gate layer 520 is positioned on sides and above the gate dielectric layer 518. Moreover, the vertical compound semiconductor 500 comprises an electrode layer 516 positioned above the upper channel layer 514 of the channel layer in the film thickness direction 502. Sides of the electrode layer 516 extend beyond sides of the channel layer 512 in an element thickness direction 504 perpendicular to the film thickness direction 502.

In one embodiment, a middle portion of the channel layer 512 between the lower channel layer 510 and the upper channel layer 514 may include InGaAs, the lower channel layer 510 may include Si-doped InGaAs, the upper channel layer 514 may include Si-doped InGaAs, the gate dielectric layer 518 may include a dielectric material, such as SiO₂, SiON, ZrO₂, HfO₂, and Al₂O₃, the gate layer 520 may include any suitable material known in the art, such as doped polysilicon, W, TaN, TiNi, TiN, etc., and combinations thereof, and the electrode layer 516 may include any suitable material known in the art, such as doped polysilicon, W, TaN, TiNi, TiN, etc., and combinations thereof.

Above the vertical compound semiconductor 500, in one embodiment, may be positioned a pMTJ. The pMTJ may be electrically coupled to the electrode layer 516 in this embodiment.

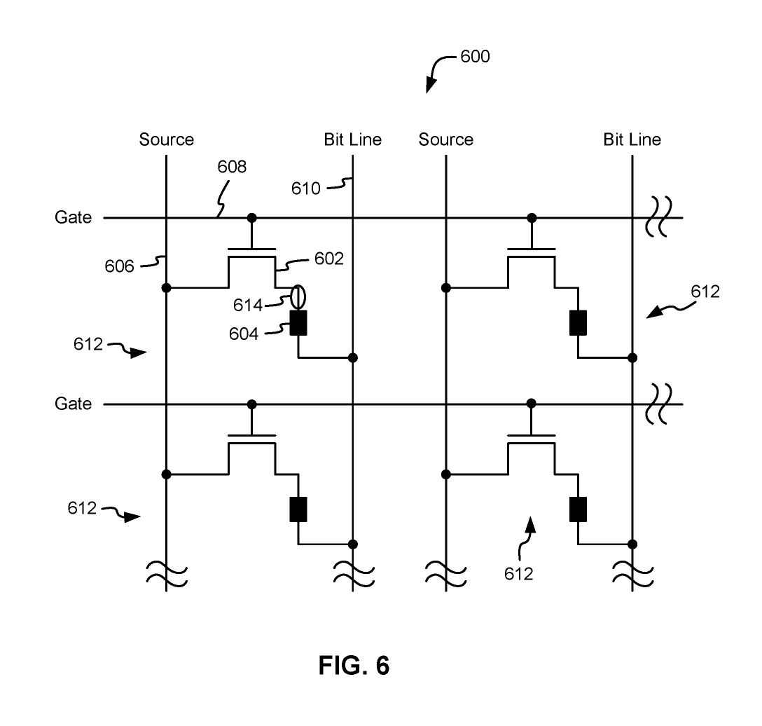

Now referring to FIG. 6, a circuit diagram of a portion of an acceptor structure 600 is shown according to one embodiment. Vertical compound semiconductors 614, such as those disclosed herein, may be used in the acceptor structure 600 or some portion thereof in various embodiments.

As shown, each cell of the acceptor structure 600 includes a transistor 602 and a pMTJ 604 coupled in series across a source line 606 and a bit line 610. Each transistor 602 is also connected to a gate pad 608. A plurality of cells 612 may be included in the acceptor structure 600 that are about equal to a number of cells in a donor structure. Each cell 612 may include the transistor 602 coupled to the pMTJ 604 in series using a vertical compound semiconductor 614 as disclosed herein, with connections for the source line 606 and the bit line 610 and a pad for the gate 608.

While various embodiments have been described above, it should be understood that they have been presented by way of example only and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method, comprising:
forming a mask layer above a substrate in a film thickness direction;
removing a portion of the mask layer to expose a portion of the substrate therethrough, the portion of the substrate having a predetermined size;
doping the portion of the substrate;
forming a channel layer above the doped portion of the substrate, wherein the channel layer extends beyond the mask layer in the film thickness direction;
forming an insulative layer above the channel layer and the mask layer in the film thickness direction, and on sides of the channel layer;
forming a gate layer above the insulative layer in the film thickness direction;
forming a second insulative layer above the gate layer in the film thickness direction;
removing portions of the insulative layer, the gate layer, and the second insulative layer to expose an upper portion of the channel layer; and
forming an electrode layer above the upper portion of the channel layer in the film thickness direction to form a nanowire, wherein sides of the electrode layer extend beyond sides of the channel layer in an element thickness direction perpendicular to the film thickness direction.

2. The method as recited in claim 1,
wherein the substrate comprises Si(111),
wherein the mask layer comprises SiO₂,
wherein the channel layer comprises InGaAs,
wherein the gate layer comprises a material selected from a group consisting of: doped polysilicon, W, TaN, TiNi, and TiN, and
wherein the electrode layer comprises a material selected from a group consisting of:
doped polysilicon, W, TaN, TiNi, and TiN.

3. The method as recited in claim 2, further comprising:
in-situ doping a lower portion of the channel layer opposite the upper portion of the channel layer in the film thickness direction with Si to form Si-doped InGaAs; and
in-situ doping the upper portion of the channel layer with Si to form Si-doped InGaAs.

4. The method as recited in claim 1, wherein the electrode layer is formed by:
depositing electrode material above the gate layer and the second insulative layer;
removing portions of the electrode material that are not positioned above the channel layer; and
forming a third insulative layer above the second insulative layer that is not covered by remaining portions of the electrode material in the film thickness direction to form the electrode layer.

5. The method as recited in claim 1, further comprising transforming Si(111) in the doped portion of the substrate into a (111)B orientation via V-incorporated Si³⁺ and/or III-terminated Si¹⁺.

6. The method as recited in claim 1, further comprising forming a perpendicular magnetic tunnel junction (pMTJ) above the electrode layer in the film thickness direction, wherein the nanowire is electrically coupled to the pMTJ.

7. The method as recited in claim 1, further comprising doping the substrate to form a lower electrode comprising doped polysilicon.

8. The method as recited in claim 1, further comprising simultaneously repeating the method at different positions on the substrate to form a plurality of nanowires above the substrate.

9. A method, comprising:
forming an etch-stop layer above a substrate in a film thickness direction;
forming a sacrificial layer above the etch-stop layer in the film thickness direction;
removing portions of the sacrificial layer and the etch-stop layer to form a pillar having a predetermined size;
forming an insulative layer above the pillar and exposed portions of the substrate that are not covered by the pillar in the film thickness direction;
removing portions of the insulative layer to thin the insulative layer and expose an upper surface of the pillar;
removing all remaining portions of the sacrificial layer to form a channel mold;
forming a channel layer above the etch-stop layer within the channel mold, wherein the channel layer extends to a height of the channel mold in the film thickness direction;
removing the channel mold;
forming a gate dielectric layer above the substrate and the channel layer in the film thickness direction, and along sides of the etch-stop layer and the channel layer;
forming a second insulative layer above portions of the gate dielectric layer that are positioned directly above the substrate, the second insulative layer having a height in the film thickness direction less than half of a height of the channel layer in the film thickness direction;
forming a gate layer above the second insulative layer, the gate layer having a height in the film thickness direction that is less than the height of the channel layer in the film thickness direction; and
forming an electrode layer directly above the channel layer to form a nanowire, wherein sides of the electrode layer extend beyond sides of the channel layer in an element thickness direction perpendicular to the film thickness direction.

10. The method as recited in claim 9, further comprising simultaneously repeating the method at different positions on the substrate to form a plurality of nanowires above the substrate.

11. The method as recited in claim 9,
wherein the substrate comprises Si(111),
wherein the channel layer comprises InGaAs,
wherein the gate layer comprises a material selected from a group consisting of: doped polysilicon, W, TaN, TiNi, and TiN, and
wherein the electrode layer comprises a material selected from a group consisting of: doped polysilicon, W, TaN, TiNi, and TiN.

12. The method as recited in claim 11, further comprising:
in-situ doping a lower portion of the channel layer closest to the substrate in the film thickness direction with Si to form Si-doped InGaAs; and
in-situ doping an upper portion of the channel layer farthest from the substrate with Si to form Si-doped InGaAs.

13. The method as recited in claim 9, further comprising:
forming a third insulative layer above the gate layer in the film thickness direction;
removing portions of the third insulative layer and the gate dielectric layer to expose an upper surface of the channel layer; and
planarizing the third insulative layer and the upper surface of the channel layer prior to forming the electrode layer.

14. The method as recited in claim 9, further comprising forming a perpendicular magnetic tunnel junction (pMTJ) above the electrode layer in the film thickness direction.

15. The method as recited in claim 9, further comprising removing the substrate and the etch-stop layer to expose a lower surface of the channel layer.

16. An apparatus, comprising:
a channel layer positioned above a substrate in a film thickness direction, the channel layer comprising a lower channel layer positioned below an upper channel layer in the film thickness direction;
a gate dielectric layer positioned on sides of the channel layer;
a gate layer positioned on sides of the gate dielectric layer; and
an electrode layer positioned above an upper portion of the channel layer in the film thickness direction, wherein sides of the electrode layer extend beyond sides of the channel layer in an element thickness direction perpendicular to the film thickness direction.

17. The apparatus as recited in claim 16,
wherein the substrate comprises Si(111),
wherein a portion of the channel layer between the lower and upper channel layers comprises InGaAs,
wherein the lower channel layer comprises Si-doped InGaAs,
wherein the upper channel layer comprises Si-doped InGaAs,
wherein the gate dielectric layer comprises a material selected from a group consisting of: SiO₂, SiON, ZrO₂, HfO₂, and Al₂O₃,
wherein the gate layer comprises a material selected from a group consisting of: doped polysilicon, W, TaN, TiNi, and TiN, and
wherein the electrode layer comprises a material selected from a group consisting of: doped polysilicon, W, TaN, TiNi, and TiN.

18. The apparatus as recited in claim 17, wherein a portion of the substrate in direct contact with the lower channel layer comprises Si(111)B.

19. The apparatus as recited in claim 16, further comprising a perpendicular magnetic tunnel junction (pMTJ) positioned above the electrode layer in the film thickness direction, wherein the pMTJ is electrically coupled to the electrode layer.

20. The apparatus as recited in claim 16, further comprising an insulative layer positioned on sides of the channel layer and the electrode in an element width direction perpendicular to the film thickness direction, the insulative layer comprising a dielectric material.
